(19) United States
(12) Patent Application Publication
(10) Pub. No.: US 2012/0260977 A1
(43) Pub. Date: Oct. 18, 2012

(54) RAPID MOUNTING SYSTEM FOR SOLAR MODULES

(75) Inventor: Robert Stancel, Los Altos Hills, CA (US)

(73) Assignee: NANOSOLAR, INC., San Jose, CA (US)

(21) Appl. No.: 13/530,375

(22) Filed: Jun. 22, 2012

Related U.S. Application Data
(63) Continuation of application No. 12/177,133, filed on Jul. 21, 2008, now abandoned.
(60) Provisional application No. 60/950,986, filed on Jul. 20, 2007.

(51) Int. Cl. H01L 31/048; B23P 11/00; H01L 31/18

(52) U.S. Cl. 136/251; 29/890.033; 29/428

(57) ABSTRACT

Methods and devices are provided for rapid solar module installation. In one embodiment, a photovoltaic module is provided comprising of a plurality of photovoltaic cells positioned between a transparent module layer and a backside module layer. The module may be a frameless module. The module may have brackets that slidably engage a mounting structure.

### CROSS-REFERENCE TO RELATED APPLICATIONS

This application is a continuation of U.S. patent application Ser. No. 12/177,133, filed Jul. 21, 2008, and entitled “Rapid Mounting System for Solar Modules, which claims the benefit of priority to U.S. Provisional Application Ser. No. 60/950,986 filed Jul. 20, 2007; both of which are fully incorporated herein by reference for all purposes.

### FIELD OF THE INVENTION

This invention relates generally to photovoltaic devices, and more specifically, to solar cells and/or solar cell modules designed for large-scale electric power generating installations.

### BACKGROUND OF THE INVENTION

Solar cells and solar cell modules convert sunlight into electricity. Traditional solar cell modules are typically comprised of polycrystalline and/or monocrystalline silicon solar cells mounted on a support with a rigid glass top layer to provide environmental and structural protection to the underlying silicon based cells. This package is then typically mounted in a rigid aluminum or metal frame that supports the glass and provides attachment points for securing the solar module to the installation site. A host of other materials are also included to make the solar module functional. This may include junction boxes, bypass diodes, sealants, and/or multi-contact connectors used to complete the module and allow for electrical connection to other solar modules and/or electrical devices. Certainly, the use of traditional silicon solar cells with conventional module packaging is a safe, conservative choice based on well understood technology.

Drawbacks associated with traditional solar module package designs, however, have limited the ability to install large numbers of solar panels in a cost-effective manner. This is particularly true for large scale deployments where it is desirable to have large numbers of solar modules setup in a defined, dedicated area. Traditional solar module packaging comes with a great deal of redundancy and excess equipment cost. For example, a recent installation of conventional solar modules in Pocking, Germany deployed 57,912 monocrystalline and polycrystalline-based solar modules. This meant that there were also 57,912 junction boxes, 57,912 aluminum frames, untold meters of cablings, and numerous other components. These traditional module designs inherit a large number of legacy parts that hamper the ability of installers to rapidly and cost-efficiently deploy solar modules at a large scale.

Although subsidies and incentives have created some large solar-based electric power installations, the potential for greater numbers of these large solar-based electric power installations has not been fully realized. There remains substantial improvement that can be made to photovoltaic cells and photovoltaic modules that can greatly increase their ease of installation, and create much greater market penetration and commercial adoption of such products.

### SUMMARY OF THE INVENTION

Embodiments of the present invention address at least some of the drawbacks set forth above. The present invention provides for the improved solar module designs that reduce manufacturing costs and redundant parts in each module. These improved module designs are well suited for rapid installation. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

Although not limited to the following, the embodiments of the present invention provides a rapid mounting system wherein the modules may have pre-mounted structure that slidably engage a support member attached to the support surface or the ground. The structure may be a bracket or some molded or shaped portion of the module (integrally formed with the module or added separately). Slidable engagement allows for reduced mounting time. Using clips, rapid release clamps or the like may also speed installation. In some embodiments, these modules may be used as building integrated material and replace items such as roofing tiles or windows, or other building materials. Optionally, the modules do not replace building materials but are used in conjunction with or over such building materials.

In one embodiment of the present invention, a photovoltaic module mounting system is provided comprising of a plurality of photovoltaic cells positioned between a transparent module layer and a backside module layer; and one or more mounting brackets in contact with the module. Optionally, the brackets have a C cross-sectional shape and configured to mate to another bracket mounted on a roof or mounting surface.

Any of the embodiments herein may be adapted to include the following features. By way of nonlimiting example, the module is a frameless module, without a full perimeter frame. Optionally, the module is a partially framed module. Optionally, the module is a fully framed module. Such a module has full perimeter frame, typically constructed of aluminum. Optionally, the brackets are configured to slidably engage a mounting structure. Optionally, the system further comprises a retaining apparatus inside at least one of the brackets. Optionally, the brackets are configured to restrain movement of the module in at least one axis. Optionally, the brackets are configured to restrain movement of the module in a first axis and a second axis.

In another embodiment of the present invention, a photovoltaic module mounting method is provided comprising providing a plurality of photovoltaic cells positioned between a transparent module layer and a backside module layer; attaching one or more mounting brackets in contact with the backside module layer; and sliding the module onto a support apparatus, wherein the mounting brackets are oriented to prevent movement of the module in at least one axis.

Any of the embodiments herein may be adapted to include the following features. By of nonlimiting example, the brackets may be configured to slidably engage a mounting structure. Optionally, the brackets are coupled to a perimeter frame of the module. Optionally, the mounting method comprises placing the mounting structure on a roof, applying foam over at least a portion of the roof and the mounting structure to hold them together, and then sliding the modules with the mounting brackets in place.

In yet another embodiment of the present invention, a photovoltaic module mounting method for use with a roof is provided. In one embodiment, method comprises placing the mounting structure on a roof; applying foam over at least a portion of the roof and the mounting structure to hold them together; providing a plurality of photovoltaic cells positioned between a transparent module layer and a backside module layer, the module having one or more mounting brackets in contact with the backside module layer; and sliding the module onto a support apparatus, wherein the mounting brackets are oriented to prevent movement of the module in at least one axis.

Any of the embodiments herein may be adapted to include the following features. By way of nonlimiting example, the module may be a frameless module. Optionally, the module is a partially framed module. Optionally, the module is a fully framed module. Optionally, the bracket includes a retaining apparatus inside at least one of the brackets. Optionally, the brackets are configured to restrain movement of the module in at least one axis. Optionally, the brackets are configured to restrain movement of the module in a first axis and a second axis.

A further understanding of the nature and advantages of the invention will become apparent by reference to the remaining portions of the specification and drawings.

### BRIEF DESCRIPTION OF THE DRAWINGS

FIG. 1 is an exploded perspective view of a module according to one embodiment of the present invention.

FIG. 2 shows a cross-section of the module of FIG. 1.

FIGS. 3 and 4 show various views of C-shaped mounting brackets according to one embodiment of the present invention.

FIGS. 5 and 6 show another embodiment of a mounting bracket according to one embodiment of the present invention.

FIGS. 7 and 8 show yet another embodiment of a mounting bracket according to one embodiment of the present invention.

FIGS. 9 and 10 show C-shaped brackets mounted in opposite orientations according to one embodiment of the present invention.

FIG. 11 shows a perspective view of another embodiment of mounting brackets according to one embodiment of the present invention.

FIGS. 12-14 show still further embodiments of mounting brackets according to embodiments the present invention.

FIGS. 15-18 show still further embodiments of mounting brackets according to embodiments the present invention.

FIGS. 19-21 show still further embodiments of mounting brackets according to embodiments the present invention.

FIGS. 22-26 show still further embodiments of mounting brackets according to embodiments the present invention.

FIGS. 27-28 show still further embodiments of mounting brackets with different cross-sections according to embodiments the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Module

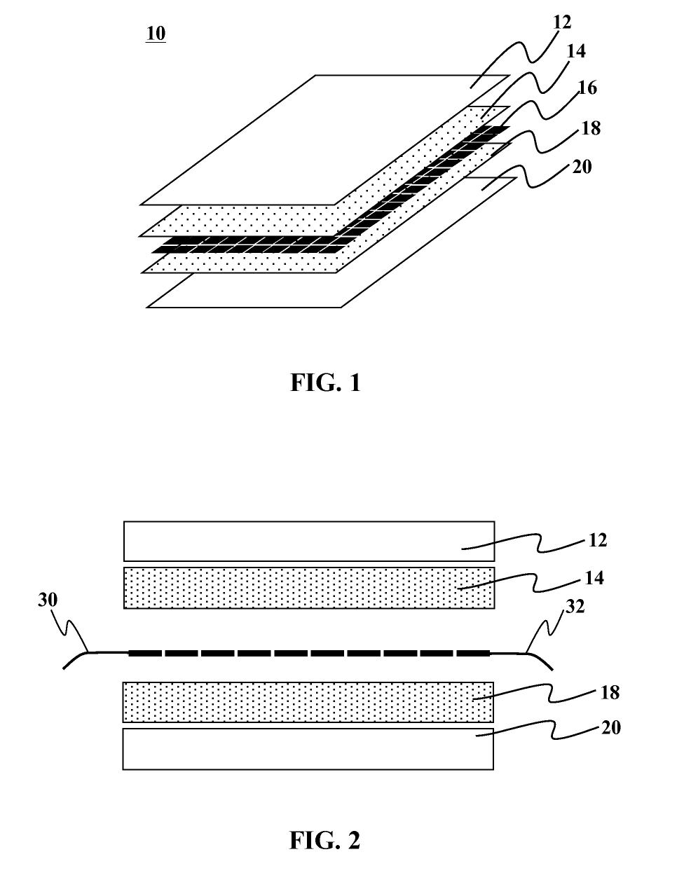

Referring now to FIG. 1, one embodiment of a module 10 according to the present invention will now be described. Traditional module packaging and system components were developed in the context of legacy cell technology and cost economics, which had previously led to very different panel and system design assumptions than those suited for increased product adoption and market penetration. The cost structure of solar modules includes both factors that scale with area and factors that are fixed per module. Module 10 is designed to minimize fixed cost per module and decrease the incremental cost of having more modules while maintaining substantially equivalent qualities in power conversion and module durability. In this present embodiment, the module 10 may include improvements to the backsheet, frame modifications, thickness modifications, and electrical connection modifications.

FIG. 1 shows that the present embodiment of module 10 may include a rigid transparent upper layer 12 followed by a pottant layer 14 and a plurality of solar cells 16. Below the layer of solar cells 16, there may be another pottant layer 18 of similar material to that found in pottant layer 14. Beneath the pottant layer 18 may be a layer of backsheet material 20. The transparent upper layer 12 provides structural support and acts as a protective barrier. By way of nonlimiting example, the transparent upper layer 12 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. In one embodiment, the total thickness of the glass or multi-layer glass may be in the range of about 2.0 mm to about 13.0 mm, optionally from about 2.8 mm to about 12.0 mm. Optionally, the thickness may be between about 0.2 mm to about 14.0 mm. In one embodiment, the top layer 12 has a thickness of about 3.2 mm. In another embodiment, the backlayer 20 has a thickness of about 2.0 mm. As a nonlimiting example, the pottant layer 14 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. Optionally, some embodiments may have more than two pottant layers. The thickness of a pottant layer may be in the range of about 10 microns to about 1000 microns, optionally between about 25 microns to about 500 microns, and optionally between about 50 to about 250 microns. Others may have only one pottant layer (either layer 14 or layer 16). In one embodiment, the pottant layer 14 is about 75 microns in cross-sectional thickness. In another embodiment, the pottant layer 14 is about 50 microns in cross-sectional thickness. In yet another embodiment, the pottant layer 14 is about 25 microns in cross-sectional thickness. In a still further embodiment, the pottant layer 14 is about 10 microns in cross-sectional thickness. The pottant layer 14 may be solution coated over the cells or optionally applied as a sheet that is laid over cells under the transparent module layer 12.

It should be understood that the simplified module 10 is not limited to any particular type of solar cell. The solar cells 16 may be silicon-based or non-silicon based solar cells. By way of nonlimiting example the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. Advantageously, thin-film solar cells have a substantially reduced thickness as compared to silicon-based cells. The decreased thickness and concurrent reduction in weight allows thin-film cells to form modules that are significantly thinner than silicon-based cells without substantial reduction in structural integrity (for modules of similar design).

The pottant layer 18 may be any of a variety of pottant materials such as but not limited to EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof as previously described for FIG. 1. The pottant layer 18 may be the same or different from the pottant layer 14. Further details about the pottant and other protective layers can be found in commonly assigned, co-pending U.S. patent application Ser. No. 11/462,359 (Attorney Docket No. NSL-090) filed Aug. 3, 2006 and fully incorporated herein by reference for all purposes. Further details on a heat sink coupled to the module can be found in commonly assigned, co-pending U.S. patent application Ser. No. 11/465,783 (Attorney Docket No. NSL-089) filed Aug. 18, 2006 and fully incorporated herein by reference for all purposes.

FIG. 2 shows a cross-sectional view of the module of FIG. 1. By way of nonlimiting example, the thicknesses of backsheet 20 may be in the range of about 10 microns to about 1000 microns, optionally about 20 microns to about 500 microns, or optionally about 25 to about 250 microns. Again, as seen for FIG. 2, this embodiment of module 10 is a frameless module without a central junction box. The present embodiment may use a simplified backsheet 20 that provides protective qualities to the underside of the module 10. As seen in FIG. 1, the module may use a rigid backsheet 20 comprised of a material such as but not limited to annealed glass, heat strengthened glass, tempered glass, flow glass, cast glass, or similar materials as previously mentioned. The rigid backsheet 20 may be made of the same or different glass used to form the upper transparent module layer 12. Optionally, in such a configuration, the top sheet 12 may be a flexible top sheet such as that set forth in U.S. Patent Application Ser. No. 60/806,096 (Attorney Docket No. NSL-085P) filed Jun. 28, 2006 and fully incorporated herein by reference for all purposes. In one embodiment, electrical connectors 30 and 32 may be used to electrically couple cells to other modules or devices outside the module 10.

### Rapid Module Mounting System

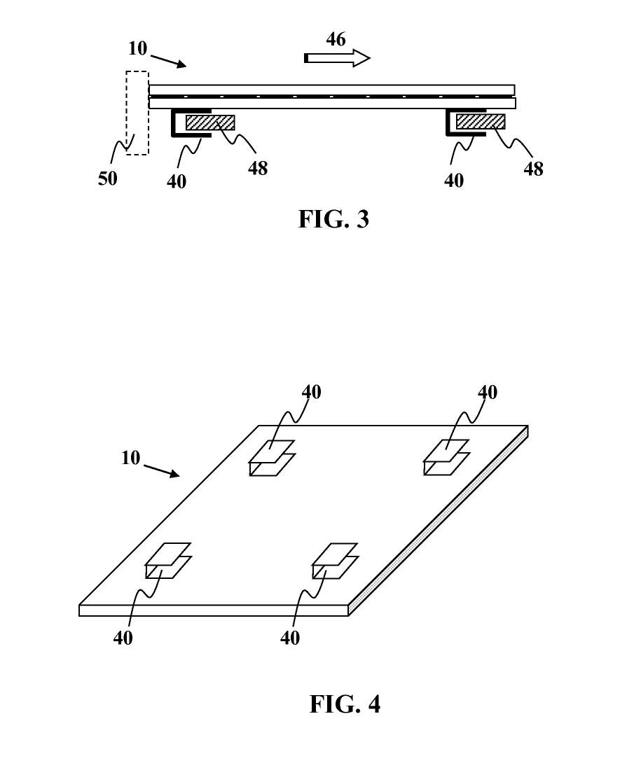

Referring now to FIG. 3, one embodiment of the present invention will now be described. FIG. 3 shows a cross-sectional view of a module 10 with one embodiment of a rapid mounting system. It should be understood that thin-film, silicon, or other absorber type solar modules may be adapted for use with the present mounting system. Embodiments of the present invention may be used with modules that may be framed or frameless. They may use edge mounted junction box(es), a central junction box, and/or multiple central junction boxes. This present embodiment of the rapid mounting system comprises of a plurality of C-shaped brackets 40 coupled to the module 10. The coupling may occur by various techniques and may include one or more of the following: adhesives, epoxy, mechanical retainers, screws, bolts, clamps, clips, or combinations thereof. The coupling techniques may be applicable to any of the embodiments herein. Optionally, other techniques may also be used. The C cross-sectional shaped brackets 40 may be comprised of various materials which provide sufficient strength to hold the module 10 in place. These materials include but are not limited to metals such as aluminum, steel, stainless steel, iron, copper, tin, or combinations thereof. Any metal material may optionally be coated with a polymer or other coating material to provide electrical insulation, surface texturing or treatment, padding, or other purpose. Optionally, the brackets 40 may be comprised of hardened polymer, plastic, or the like instead of or used in combination with metal. The brackets 40 may be mounted to engage an underside, side edge, and/or top side surface of the module 10.

As seen in FIG. 3, this embodiment shows the brackets 40 mounted on the underside of the module 10. As the module is moved laterally as indicated by arrow 46, the brackets 40 will engage battens or other supports 48 on the mounting surface. In this embodiment, the mounting surface may be a roof (finished or unfinished). In other embodiments, that mounting surface may be on a building facade, in a dedicated energy generation facility, an open field, or other sun exposed area. After the brackets 40 engage support 48, the brackets 40 may be locked into position. This may occur by clamps, adhesives, mechanical retention, or other method of attachment between the bracket 40 and the support 48. Optionally, some embodiments may use no mechanical or adhesive attachment between the bracket 40 and support 48. Optionally, some embodiments may use a separate retainer device 50 such as but not limited to a spacer, stake, or other position retainer to hold the module in place and prevent movement in a direction that allows the brackets 40 to fully and/or partially disengage from the support 48. The retainer 50 may be positioned to engage the module 10 and/or the bracket 40.

As seen in FIG. 4, an underside of the module 10 is shown. This figure shows an embodiment where four (4) brackets 40 are coupled to the underside of the module 10. Some embodiments may have three brackets 40. Some embodiments may have two brackets 40. Some embodiments may have one bracket 40. Optionally, some may be more than four brackets 40. Some embodiments may have all the brackets 40 in one row. Optionally, some may have brackets 40 in two rows. Optionally, some may have brackets 40 in three rows. Optionally, some may have brackets 40 in four rows. Optionally, some embodiments may have different number of brackets in the rows. Optionally, some brackets may be different sized or oriented in different directions.

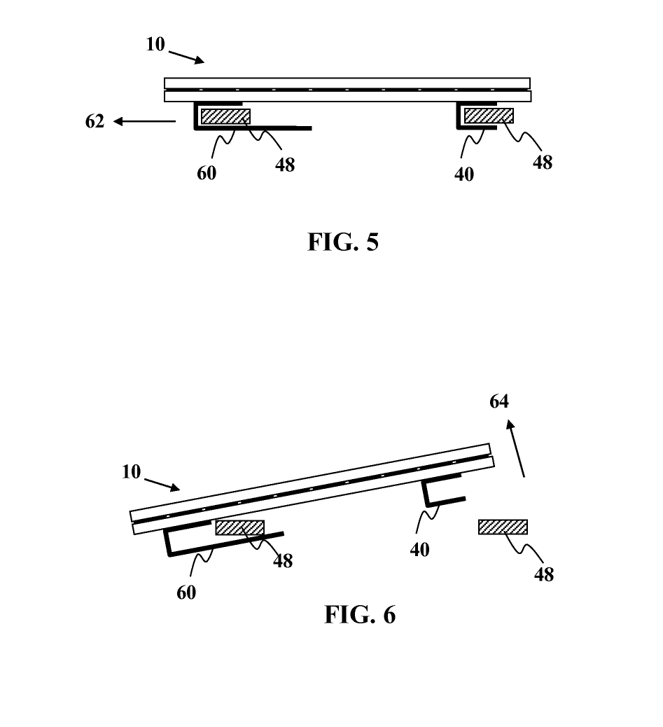

FIG. 5 shows a still further embodiment of the present invention. In this embodiment, at least one of the brackets comprises of an extended lip bracket 60 which allows for one edge of the module to be lifted up while not completely disengaging from support 48. As seen in FIG. 5, the module may be moved laterally as indicated by arrow 62. This movement allows for one set of brackets 40 to disengage from support 48. Support 48 may be support rail, a roof batten, or the like.

As seen in FIG. 6, with one set of brackets 40 disengaged, at least one edge of the module 10 may be lifted upward as indicated by arrow 64. This allows for the extended lip bracket to be still be engaged with the support 48 but have either sufficient gap or flexibility (due to the increased length of the lip which provides greater flexibility).

### Foamed or Fixed Roofing Supports

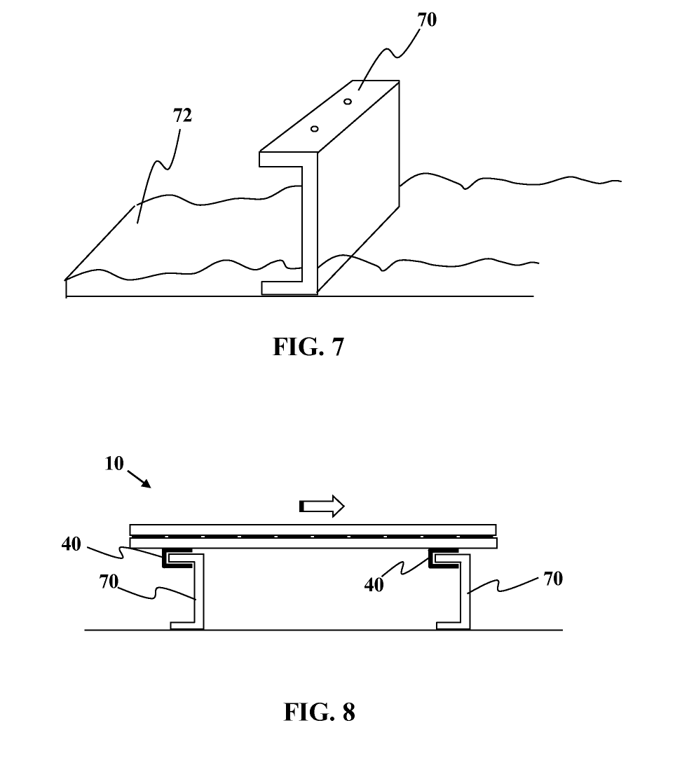

Referring now to FIG. 7, a side view of a stand-off or support member 70 is shown. In this embodiment of the present invention, this stand-off 70 may be foamed in place by foam 72 which may be added to the structure. This type of stand-off 70 may be of particular use on roofing surfaces (flat or angled). These stand-off 70 provide excellent pre-mounted support for attachment of the modules 10. Of course, other attachment techniques, such as but not limited to weight, adhesives, fasteners, and/or ballast may be used with or in place of the foregoing.

As seen in FIG. 8, the module brackets 40 may easily slidably engage the stand-off 70. In some embodiments, the stand-offs 70 are positioned to engage the brackets 40. Optionally, the brackets are positioned under the module to accommodate the stand-offs 70. Whichever item is fixed in position first, the corresponding item is mounted to accommodate and engage. The module may be mounted in landscape or portrait orientation over the stand-offs 70. Optionally, there is at least on stand-off 70 beneath each module. In some embodiments, there are at least two stand-offs 70 underneath the module 10. Optionally, the stand-offs 70 are spaced so that there are at least two stand-offs per module.

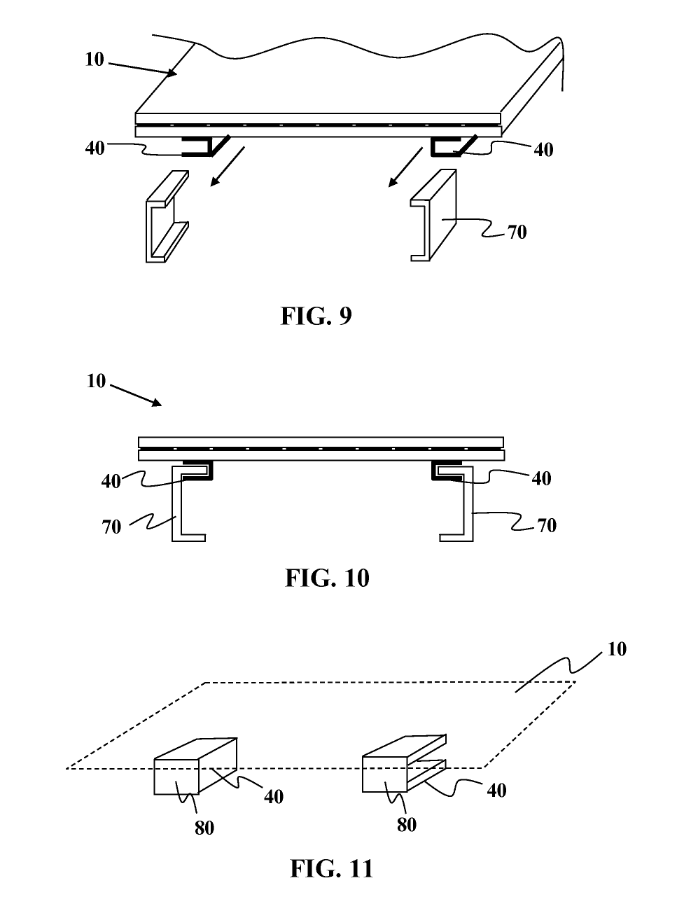

FIG. 9 shows yet another embodiment wherein the brackets are slid onto the stand-offs 70. As seen in FIG. 9, the brackets 40 are oriented to have their open sides pointed in different directions. This orientation provides greater support to hold the module in place from lateral forces. FIG. 9 shows that with the brackets 40 oriented in this opposing direction, the brackets 40 will need to be slid on to stand-offs 70 in a direction parallel to the length-wise orientation of the stand-offs 70. The stand-off 70 may be shorter than the module. Optionally, the stand-offs 70 may very long (longer than one module or longer than multiple modules) and the modules may be slid thereon. The orientation of the brackets and their C-shape prevents movement (push or pull) in at least one axis.

FIG. 10 shows a side cross-sectional view of the opposing oriented brackets 40 on the module 10. It should be understood that there may be one, two, three or more rows of such brackets 40 per module.

Referring now to FIG. 11, a still further embodiment is shown. This embodiment use stops or stop surfaces 80 on one or more of the brackets 40. This prevents excessive motion in one axis. This prevents the brackets 40 from sliding off the stand-offs 70. Some embodiments have at least one bracket 40 with a stop 80. Optionally, some embodiments have at least two brackets 40 each with a stop 80. Optionally, some embodiments have at least three brackets 40 each with a stop 80. Optionally, some embodiments have at least four brackets 40 each with a stop 80.

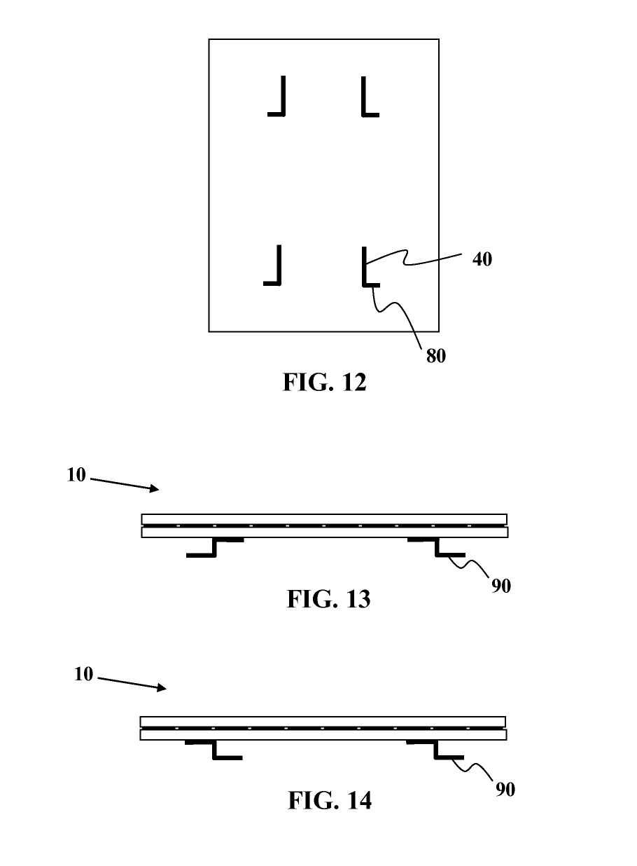

FIG. 12 shows an underside view where at least four brackets 40 each has a stop 80. Optionally, less than all of the brackets 40 have stops 80. Optionally, only two brackets 40 has stops. Optionally, only one bracket 40 has a stop. The stops may be formed of the same material as the bracket 40 or different material.

FIG. 13 shows a still further embodiment, where instead of a C cross-section, brackets 90 have zig-zag or stepped cross-section is used. Again these may be aligned in the same orientation or different orientations.

FIG. 14 shows the embodiment where the stepped cross-section brackets 90 are oriented in the same direction.

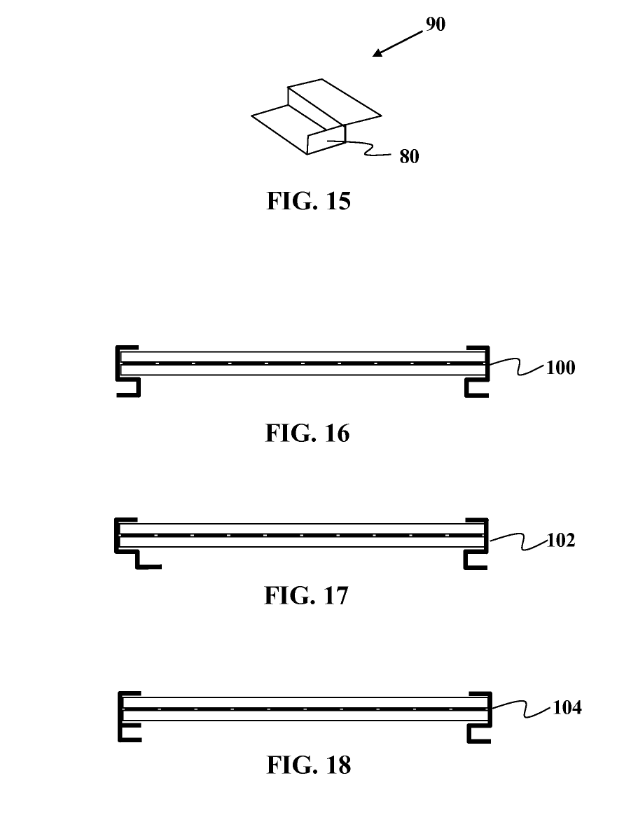

FIG. 15 shows an embodiment of stepped cross-section brackets 90 where a stop 80 is incorporated into the bracket. The orientation of the brackets may be such as to prevent motion in one axis (push-pull) and in a second axis (at least push).

FIG. 16 shows an embodiment where the bracket 100 engages at least a side surface and/or a top surface of the module 10, but with openings pointed in different directions.

FIG. 17 shows an embodiment where the bracket 102 engages at least a side surface and/or a top surface of the module 10, but with openings pointed in the same direction but using stepped cross-section.

FIG. 18 shows an embodiment where the bracket 104 engages at least a side surface and/or a top surface of the module 10, but with openings pointed in the same direction but using C cross-section.

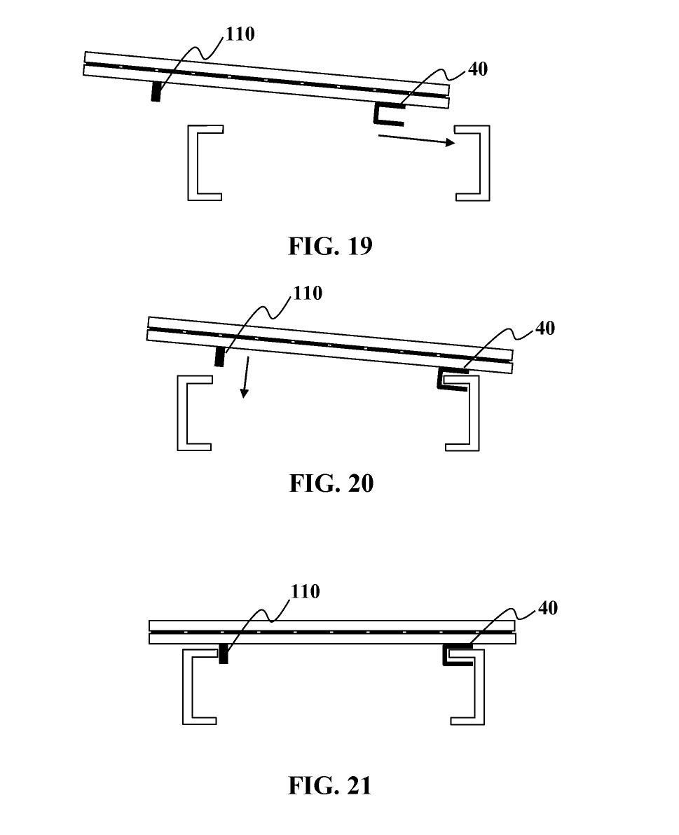

FIGS. 19 through 21 shows a sequence where only one or one set of brackets on the module is a C or stepped cross-sectional device 40. The other is merely a stop 110. This allows the module to be angled into place, but once flat or horizontal, lateral motion is prevented. Such a mounting technique may also be used with roof battens and is not limited to the brackets shown in FIGS. 19-21.

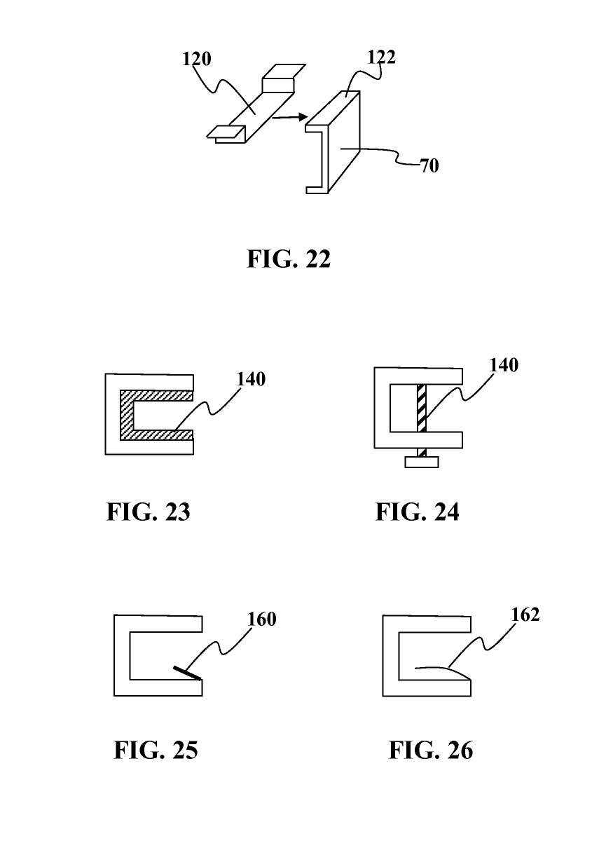

FIG. 22 shows a still further configuration of a bracket 120 wherein the bracket is configured to engage the length of the lip 122 on the stand-off 70. Some embodiments may also be used that only engage portions of the lip 122 of stand-off 70.

FIGS. 23-26 shows various treatments or features that maybe included in C, stepped, or other cross-sectional shaped brackets attached to modules such as those shown in FIGS. 1-22 or mounted on support brackets. FIG. 23 shows that an interior surface may be coated by a polymer or rubber material 140. FIG. 24 shows that a bolt, screw, or other fastener 150 may be used to lock items in position. The bolt may be oriented laterally, vertically, or other orientation to hold attachments in place. FIG. 25 and FIG. 26 shows clips, barbs, springs, or retaining features 160 and/or 162 to hold items in place once they engage inside the bracket. They may be used on one or both jaws of the bracket.

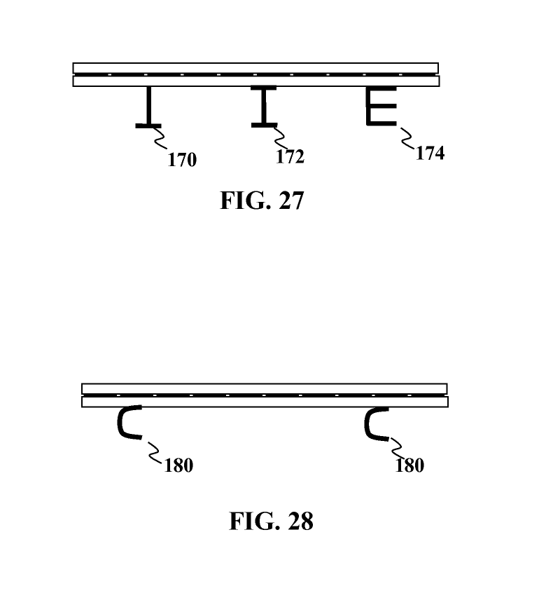

FIGS. 27 and 28 show other cross-sectional shaped brackets that maybe used singly or in combination with the same or different shaped brackets. For ease of illustration, more than one type of bracket is shown per module. This may or may not be the case. FIG. 27 shows a bracket 170 with an inverted T cross-sectional shape. FIG. 27 shows a bracket 172 with an I cross-sectional shape. FIG. 27 shows a bracket 174 with an E cross-sectional shape. FIG. 28 shows an embodiment with two curved C cross-sectional shaped brackets 180.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although glass is the layer most often described as the top layer for the module, it should be understood that other material may be used and some multi-laminate materials may be used in place of or in combination with the glass. Some embodiments may use flexible top layers or coversheets. By way of nonlimiting example, the backsheet is not limited to rigid modules and may be adapted for use with flexible solar modules and flexible photovoltaic building materials. Embodiments of the present invention may be adapted for use with superstrate or substrate designs.

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A photovoltaic module mounting system comprising:
a photovoltaic module comprising a plurality of photovoltaic cells positioned between a transparent module layer and a backside module layer; and
a bracket coupled to the photovoltaic module, wherein the bracket has a side face and an engaging face and an opening, wherein the engaging face is spaced apart from an underside of the backside module layer by the side face, and wherein the opening is opposite the side face;
wherein the bracket is capable of engaging a support member, wherein at least a portion of the support member is configured to fit into the opening of the bracket and engage the engaging face and the side face of the bracket.

2. The system of claim 1 wherein the bracket slidably engages the support member through a lateral movement of the photovoltaic module.

3. The system of claim 1 wherein the bracket engages the support member through an angled movement of the photovoltaic module.

4. The system of claim 1 wherein the bracket is coupled only to the underside of the backside module layer.

5. The system of claim 4 wherein the bracket further comprises an upper face, wherein the upper face forms an S cross-sectional shape with the side face and engaging face, wherein the upper face is coupled to the backside module layer.

6. The system of claim 4 wherein the bracket further comprises an upper face, wherein the upper face forms a C cross-sectional shape with the side face and engaging face, wherein the upper face is coupled to the backside module layer.

7. The system of claim 6 wherein the engaging face of the bracket has a length that forms an extended lip relative to the upper face of the bracket.

8. The system of claim 6 further comprising a locking feature coupled to at least one of the engaging face and the upper face, wherein the locking feature is chosen from the group consisting of a polymer material, a rubber material, a bolt, a screw, a fastener, a clip, a barb, a spring, a clamp and an adhesive.

9. The system of claim 1 further comprising a locking feature coupled to the engaging face, wherein the locking feature is chosen from the group consisting of a polymer material, a rubber material, a bolt, a screw, a fastener, a clip, a barb, a spring, a clamp and an adhesive.

10. The system of claim 1 wherein the photovoltaic module has a side surface formed by the perimeter of the transparent module layer and the backside module layer, and wherein the bracket is coupled to the side surface.

11. The system of claim 1 wherein the support member is coupled to a mounting surface.

12. The system of claim 1 wherein the support member is configured as a stand-off, wherein the stand-off spaces the photovoltaic module vertically apart from the mounting surface.

13. The system of claim 1 wherein the bracket further comprises a stop surface adjoining the side face and the engaging face, wherein the stop surface restrains lateral motion in one axis.

14. The system of claim 1 wherein the photovoltaic module is one of a framed module, a partially framed module, or a frameless module.

15. A method of mounting a photovoltaic module, the method comprising:
providing a photovoltaic module, wherein the photovoltaic module comprises a plurality of photovoltaic cells positioned between a transparent module layer and a backside module layer; and
coupling a bracket to the photovoltaic module, wherein the bracket has a side face and an engaging face and an opening, wherein the engaging face is spaced apart from an underside of the backside module layer by the side face, and wherein the opening is opposite the side face;
wherein the bracket is capable of engaging a support member, wherein at least a portion of the support member is configured to fit into the opening of the bracket and be engaged by the side face and the engaging face of the bracket.

16. The method of claim 15 wherein the step of coupling the bracket comprises coupling the bracket only to the underside of the backside module layer.

17. The method of claim 16 wherein the bracket further comprises an upper face, wherein the upper face forms a C cross-sectional shape with the side face and engaging face, wherein the upper face is coupled to the backside module layer.

18. The method of claim 16 wherein the bracket further comprises an upper face, wherein the upper face forms an S cross-sectional shape with the side face and engaging face, wherein the upper face is coupled to the backside module layer.

19. The method of claim 15 wherein the support member is coupled to a mounting surface.

20. The method of claim 15 wherein the support member is configured as a stand-off, wherein the stand-off spaces the photovoltaic module vertically apart from the mounting surface, and wherein the stand-off is configured to be held to the mounting surface by a foam.
